(19) United States
(12) Patent Application Publication
(10) Pub. No.: US 2017/0338321 A1
(43) Pub. Date: Nov. 23, 2017

(54) NICKEL SILICIDE IMPLEMENTATION FOR SILICON-ON-INSULATOR (SOI) RADIO FREQUENCY (RF) SWITCH TECHNOLOGY

(71) Applicant: Newport Fab, LLC dba Jazz Semiconductor, Inc., Newport Beach, CA (US)

(72) Inventors: Paul D. Hurwitz, Irvine, CA (US); Kurt Moen, Tustin, CA (US)

(21) Appl. No.: 15/158,514

(22) Filed: May 18, 2016

(51) Int. Cl. H01L 29/45; H03K 17/687; H01L 29/786; H01L 29/66; H01L 29/417; H01L 21/285; H01L 29/40; H01L 27/12; H01L 21/768; H01L 21/3105; H04B 1/38; H01L 29/423

(52) U.S. Cl. CPC H01L 29/458; H04B 1/38; H03K 17/6872; H01L 29/78654; H01L 29/66772; H01L 29/42384; H01L 21/28518; H01L 29/401; H01L 27/1222; H01L 21/76843; H01L 21/31055; H01L 29/41733

(57) ABSTRACT

A radio frequency (RF) switch includes a plurality of series-connected silicon-on-insulator (SOI) CMOS transistors fabricated using a 0.13 micron (or larger) process, wherein the SOI CMOS transistors include nickel silicide formed on the source/drain regions. Each of the series-connected SOI CMOS transistors has a gate length of about 0.13 microns or more, thereby enabling these SOI CMOS transistors to handle high power RF signals, and exhibit the high breakdown voltages required to implement an RF switch. The nickel silicide regions advantageously contribute to a relatively a low on-resistance (R_{ON}) of the SOI CMOS transistors, while consuming a relatively small amount of the underlying silicon regions during their fabrication. The SOI CMOS transistors can be fabricated on a relatively thin silicon layer, thereby contributing to a relatively low off capacitance (C_{OFF}) of the SOI CMOS transistors. As a result, an R_{ON}*C_{OFF} value of the RF switch is advantageously minimized.

### FIELD OF THE INVENTION

The present invention relates to the use of nickel silicide in connection with the fabrication of silicon-on-insulator (SOI) CMOS transistors having gate lengths of about 0.13 microns or greater, wherein the SOI CMOS transistors are used in high power applications such as radio frequency (RF) switching.

### RELATED ART

FIG. 1 is a circuit diagram of a conventional radio frequency (RF) circuit 100, including an antenna 101, an RF receiver switch 110, an RF receiver port 115, an RF transmitter switch 120 and an RF transmitter port 125. RF receiver switch 110 includes a plurality of high-voltage field effect transistors (FETs) 110₁-110_{N}, which are connected in series (in a stack). The stack of high voltage FETs 110₁-110_{N} is controlled to route RF signals from antenna 101 to receive port 115. Similarly, RF transmitter switch 120 includes a stack of high-voltage FETs 120₁-120_{N}, which are controlled to route RF signals from transmit port 125 to antenna 101. As used herein, an RF signal is defined as a signal having a frequency in the range of about 10 kHz to 50 GHz.

Silicon-on-insulator (SOI) CMOS technologies are now the dominant platforms for creating best-in-class radio frequency switch (RFSW) products for handsets and other mobile devices. Thus, transistors 110₁-110_{N} and 120₁-120_{N} are typically implemented using SOI CMOS transistors. Such SOI CMOS transistors enable the associated RF switches 110 and 120 to transmit RF signals in the range of 0.5 GHz to 6 GHz with a high degree of linearity, while withstanding voltages of 40V to 70V and in off-state. Some early solid-state RF switches were created using silicon-on-sapphire (SOS) and Gallium-Arsenide Monolithic microwave integrated circuit (GaAs MMIC) technologies. However, SOI CMOS transistors are able to provide comparable, or better, operating characteristics than SOS and GaAs MMIC transistors at a substantially lower cost. Moreover, because SOI CMOS technology uses standard CMOS technologies and standard cell libraries, RF switches that implement SOI CMOS transistors can be readily integrated into larger system-on-chip (SOC) devices, thereby further minimizing fabrication costs.

FIG. 2 is a cross-sectional view of a conventional SOI CMOS transistor 200, which can be used to implement each of transistors 110₁-110_{N} and 120₁-120_{N}. SOI transistor 200 is fabricated on a thin silicon layer 203, which is located on an insulator 202 (e.g., silicon oxide), which in turn, is located on a substrate 201 (e.g., monocrystalline silicon). SOI transistor 200 includes a source region 204 (which includes source contact region 204A and lightly doped source region 204B), a drain region 205 (which includes drain contact region 205A and lightly doped drain region 205A), gate dielectric 206, polysilicon gate 207, dielectric sidewall spacers 208-209 and metal silicide regions 210-212. A channel region 215 exists between the source region 204 and the drain region 205.

For an RF switch, the on-resistance of the switch (R_{ON}) multiplied by the off-capacitance of the switch (C_{OFF}) is a key figure of merit, which dictates the ability to transmit RF power with low losses through on-state stacks, while maintaining adequate isolation across off-state stacks. Typically these off-state stacks need to hold off relatively high voltage RF signals (e.g., 40-70V). Consequently, RF switches are implemented with older generation SOI CMOS transistors having operating voltages in the 2.5 Volt-5 Volt range (and even higher breakdown voltages). These older generation SOI CMOS transistors are fabricated using processes with a minimum feature size of 0.13 microns or greater. In general, the gate length of each of transistors 110₁-110_{N} and 120₁-120_{N} must be about 0.2 microns or more to provide the required off-state isolation.

Silicon processing technologies used to fabricate SOI CMOS transistors having the required feature sizes (0.13 microns and up) and voltages (2.5 Volts and up) employ titanium (Ti) or cobalt (Co) as the silicide metal. Thus, metal silicide regions 210-212 are either titanium silicide (TiSi₂) or cobalt silicide (CoSi₂). For bulk and PD-SOI technologies of this generation, these materials provide sufficiently low silicide resistance (and FET access resistance) for most applications. These materials can be employed at low cost and they also tolerate the backend thermal budgets (time at temperature) associated with these technology nodes.

Thin film SOI CMOS transistors such as transistor 200 are attractive for RF switch applications, because these transistors reduce the junction capacitance component of the off-capacitance value, C_{OFF}. Scaling the thickness (T_{Si}) of the silicon layer 203 of the SOI transistors to smaller values provides one means to reduce the off-capacitance value C_{OFF}. However, reducing the thickness T_{Si} of silicon layer 203 results in significant challenges for process integration. More specifically, a reduction in the thickness T_{Si} of silicon layer 203 results in higher access resistance to the FET channel 215, contributing to a higher on-resistance value R_{ON}. In particular, more current crowding occurs in the region under the source/drain metal silicide regions 210 and 211. The thicknesses of metal silicide regions 210-211 can be reduced accordingly, by depositing a thinner titanium (or cobalt) layer (which is consumed during the silicidation process). However, this naturally leads to higher and more variable metal silicide sheet resistance in the resulting metal silicide layers 210-213. For RF switching technology in particular, this has several deleterious effects. First, a higher active silicide sheet resistance tends to increase the on-resistance value R_{ON}, as current from the gate edge sees a higher total resistance to ends of the source/drain regions 204-205. This effect can be counteracted by reducing the resistance of the source/drain extrinsic metallization. For example, the pitch of source/drain contacts (not shown) coupled to metal silicide regions 210-211 can be reduced, or the widths of the metal silicide regions 210 and 211 can be increased. However, both of these approaches undesirably increase the parasitic off-state capacitance value C_{OFF}.

The higher resistance of the gate silicide region 212 resulting from a thinner titanium (or cobalt) layer also degrades the FET noise figure of the SOI CMOS transistor 200. This will limit the performance of products that integrate low noise amplifiers on the same integrated circuit as the RF switches 110, 120 (which is common in some front-end module (FEM) integrated circuits). That is, the use of SOI CMOS transistor 200 (with a relatively high-resistance gate silicide region 212) in an integrated low noise amplifier will result in sub-optimal performance in this low noise amplifier.

In order to overcome the above-described deficiencies associated with a smaller silicon thickness T_{Si}, raised source/drain (RSD) integration has been used to increase the silicon thickness in the source/drain regions 204A and 205A by epitaxial deposition. This permits the formation of thicker source/drain silicide regions 210 and 211, but significantly complicates the process flow, and may require additional capital investment for fabs that lack epitaxial deposition equipment. Moreover, RSD integration is a challenging process to control in manufacturing, since small variations in conditions can result in poor epitaxial silicon quality.

Advanced deep sub-micron semiconductor processes (e.g. processes having minimum features sizes of 90 nm or less) have implemented nickel silicide regions in connection with SOI transistors. These transistors have aggressively scaled gate lengths of 90 nm or less, and exhibit low operating voltages. Nickel-silicided SOI transistors fabricated using these advanced deep sub-micron processes are unable to meet the power handling requirements of an RF switch application. Moreover, it would not be cost effective to use nickel-silicided SOI transistors fabricated using these advanced deep sub-micron processes in an RF switch application. This is because the fabrication cost is higher for technologies with smaller feature sizes, as it requires more expensive tooling and processing control. For digital designs, area savings typically ‘pays’ for this increased processing costs. However, for the RF switch application, the area savings are small.

Note that nickel silicide may be used in advanced deep sub-micron processes because the post-silicide thermal budgets of these processes are small enough to prevent the nickel silicide source/drain regions from transitioning from a low resistance phase to a high resistance phase. However, nickel silicide is not used in older SOI CMOS processes (e.g., SOI CMOS processes having minimum feature sizes of 0.13 microns or greater), because the post-silicide thermal budgets associated with these older processes are large enough to cause the nickel silicide regions to transition from a low resistance phase to a high resistance phase.

It would therefore be desirable to have an improved SOI CMOS transistor for implementing RF switches, wherein said SOI CMOS transistor exhibits a R_{ON}*C_{OFF} value better than previously available. It would further be desirable if this improved SOI CMOS transistor could be easily fabricated on a relatively thin silicon layer (to improve the off-capacitance C_{OFF}) without requiring RSD integration. It would further be desirable for this improved SOI CMOS transistor to include relatively thin silicide regions that exhibit a relatively low active sheet resistance, thereby providing a relatively low on-resistance R_{ON}, and enabling the transistor to be used to implement other on-chip circuitry, such as low noise amplifiers. It would further be desirable for this improved SOI CMOS transistor to be capable of handling the voltage and power requirements of RF switching applications.

### SUMMARY

Accordingly, the present invention provides an RF switch that includes a plurality of series-connected SOI CMOS transistors fabricated in accordance with a 0.13 micron (or greater) process, wherein the SOI CMOS transistors include nickel silicide formed on the source and drain regions. The SOI CMOS transistors may be fabricated on a silicon layer having a thickness (T_{Si}) less than 1000 Angstroms to minimize the off-capacitance (C_{OFF}) of the RF switch. Each SOI CMOS transistor may have a gate length of at least about 0.13 microns to provide operating/breakdown voltages acceptable for use in an RF switch, and to enable the SOI CMOS transistor to handle the power requirements of the RF switch. The nickel silicided source/drain regions may be fabricated by the deposition of a nickel layer having a thickness of about 80 to 150 Angstroms, resulting in relatively thin nickel silicided source/drain regions. The nickel silicided source/drain regions exhibit resistances and thicknesses that minimize the on-resistance R_{ON} of the RF switch.

In one embodiment, nickel silicide is also formed on the gate of the SOI CMOS transistor. As a result, the FET noise figure of the SOI CMOS transistor is relatively low, thereby enabling this transistor to be used to implement other circuitry, such as a low noise amplifier, on the same integrated circuit chip as the RF switch.

Another embodiment includes a method for fabricating the SOI CMOS transistor of the present invention. This method includes forming a silicon layer over an insulator, wherein the silicon layer may have a thickness of about 1000 Angstroms or less. A plurality of series-connected transistor structures are fabricated on the silicon layer, wherein the transistors structures include a plurality of gates, each having a gate length of at least about 0.13 microns, and a plurality of source/drain regions. A nickel layer is deposited over the source/drain regions, wherein the nickel layer may have a thickness in the range of about 80 to 150 Angstroms. The nickel layer is then reacted with the source/drain regions, thereby forming nickel silicide regions on the source/drain regions.

The nickel layer may be reacted with the source/drain regions using the following process. Initially, a first anneal is performed to form nickel silicide regions of the nickel phase, Ni₂Si. This first anneal may be performed at temperatures in the range of about 280° C. and 350° C. Unreacted portions of the nickel layer are then stripped after completing this first anneal. A second anneal is then performed to form nickel silicide regions of the low-resistance nickel phase, NiSi. This second anneal may be performed at temperatures of about 450° C.

After the nickel silicide regions of the low-resistance nickel phase, NiSi are formed, the thermal budget of the post-silicide process is controlled to ensure that the NiSi nickel silicide regions do not transition to the higher resistance nickel phase, NiSi₂. In order to accomplish this, a subsequently deposited pre-metal dielectric layer is not annealed prior to a chemical-mechanical polishing (CMP) operation. In addition, the formation of a titanium nitride (TiN) liner layer over the pre-metal dielectric layer is modified to avoid the requirement for a high thermal budget during this step.

The present invention will be more fully understood in view of the following description and drawings.

### BRIEF DESCRIPTION OF THE DRAWINGS

FIG. 1 is a circuit diagram of a conventional radio frequency (RF) circuit, including a pair of RF switches.

FIG. 2 is a cross-sectional view of a conventional SOI CMOS transistor used in the RF switches of FIG. 1.

FIGS. 3A, 3B, 3C, 3D, 3E, 3F, 3G and 3H are cross-sectional views that illustrate various steps during the fabrication of a nickel silicided SOI CMOS transistor 300 in accordance with various embodiments of the present invention.

FIG. 4 is a circuit diagram of an RF switch that includes a plurality of series-connected nickel silicided SOI CMOS transistors and a plurality of series-connected resistors in accordance with one embodiment of the present invention.

FIG. 5 is a schematic top view representing the series-connected nickel silicided SOI CMOS transistors and resistors of FIG. 4 in accordance with one embodiment of the present invention.

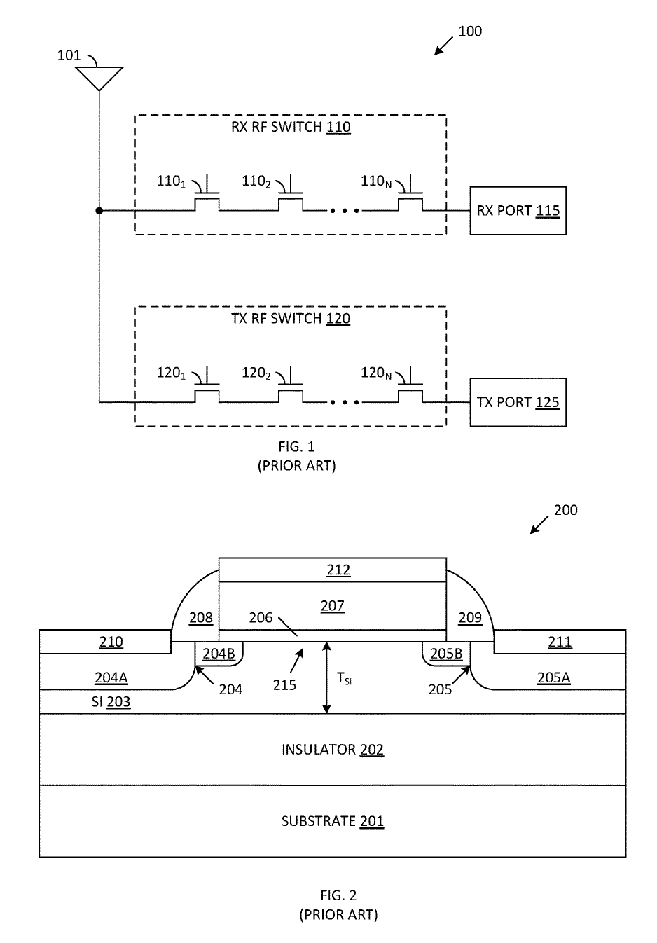

### DETAILED DESCRIPTION

In general, the present invention implements an RF switch using a plurality of series-connected SOI CMOS transistors, each having a gate length of about 0.13 microns or more, and each having nickel silicide regions formed on their source and drain regions. Because each of the series-connected SOI CMOS transistors has a gate length of about 0.13 microns or more, these SOI CMOS transistors are capable of handling high RF powers, and exhibit the high breakdown voltages required to implement an RF switch. The nickel silicide regions advantageously contribute to a relatively a low on-resistance (R_{ON}) of the SOI CMOS transistors, while consuming a relatively small amount of the underlying silicon regions during their fabrication (when compared with the formation of titanium silicide or cobalt silicide). Thus, the nickel silicided SOI CMOS transistors of the present invention can be fabricated without raised source drain (RSD) integration. In addition, the SOI CMOS transistors of the present invention can be fabricated on a relatively thin silicon layer, thereby contributing to a relatively low off capacitance (C_{OFF}) of the SOI CMOS transistors. As a result, the R_{ON}*C_{OFF} value of the RF switch is advantageously minimized.

The present invention also includes methods for fabricating an RF switch including a plurality of series-connected SOI CMOS transistors, each having a gate length of about 0.13 microns or more, and each having nickel silicide regions formed on their source and drain regions. These methods can be implemented with only minor modifications to a conventional SOI CMOS process, and do not require epitaxial growth to raise the source/drain regions of the SOI transistors.

The present invention will now be described in more detail.

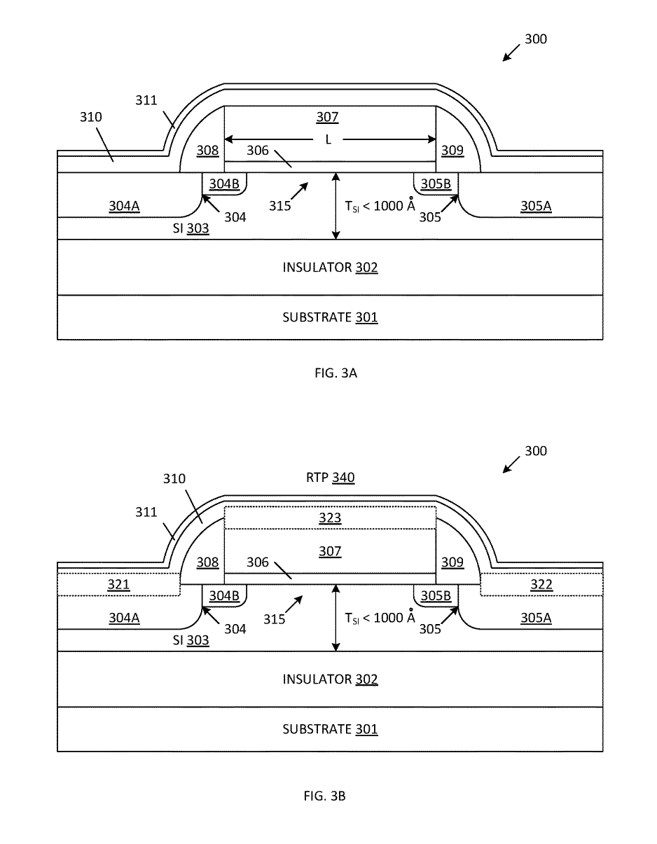

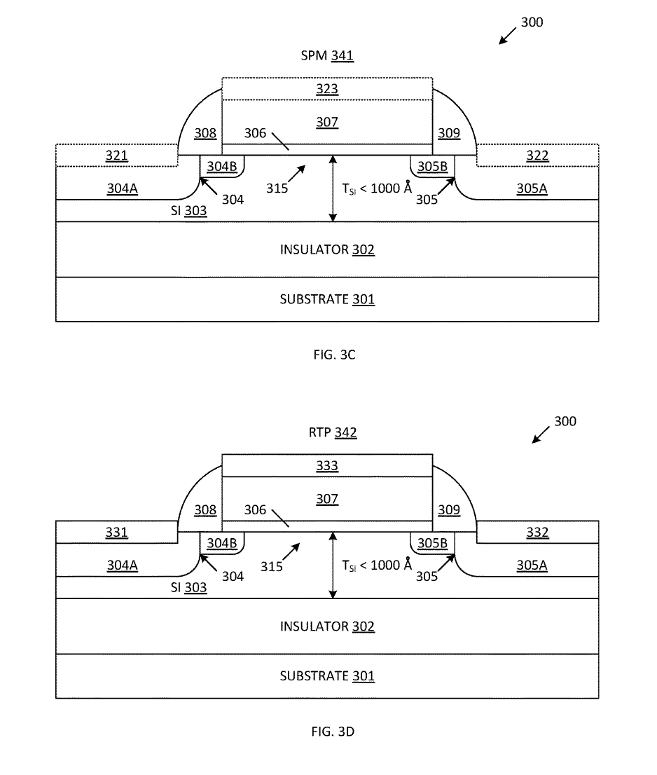

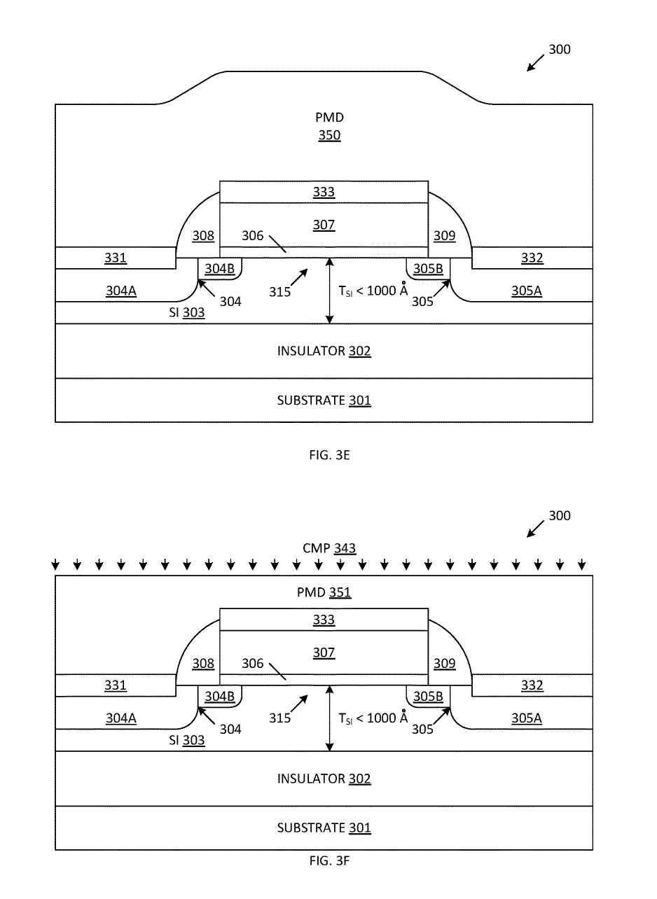

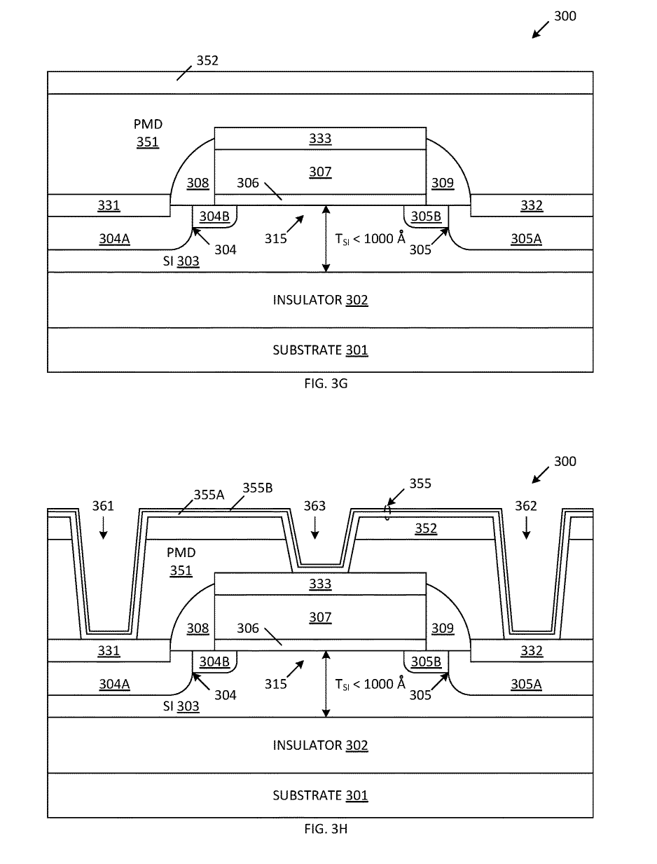

FIGS. 3A-3H are cross-sectional views that illustrate various steps during the fabrication of a nickel silicided SOI CMOS transistor 300 in accordance with various embodiments of the present invention. As described in more detail below, transistors having the same construction as SOI CMOS transistor 300 are used to form an RF switch (and may also be used to form other circuitry, such as low noise amplifiers, on the same integrated circuit chip).

As illustrated in FIG. 3A, an insulator layer 302 is formed over a substrate 301. In one embodiment, substrate 301 may include a 300 mm monocrystalline silicon wafer, and insulator layer 302 may be a layer of silicon oxide having a thickness of about 1000 to 10000 Angstroms. Other conventional materials can be used to implement substrate 301 and insulator layer 302 in other embodiments. Monocrystalline silicon layer 303 is formed over insulator layer 302. In accordance with one embodiment, silicon layer 303 has a thickness (T_{Si}) less than about 1000 Angstroms. In a particular embodiment, silicon layer 303 has a thickness T_{Si} of about 800 Angstroms. This relatively thin silicon layer 303 advantageously contributes to a relatively small off-capacitance (C_{OFF}) of transistor 300. Silicon layer 303 can be formed in various manners known to those of ordinary skill in the art, including SIMOX (separation by implantation of oxygen), wafer bonding, or seed growth (wherein silicon layer 303 is grown over insulator layer 302). In the described embodiments, silicon layer 303 has a p-type conductivity, such that the resulting transistor 300 is an NMOS transistor. However, it is understood that conductivity types specified herein can be reversed in other embodiments.

Gate dielectric 306 and polysilicon gate 307 are formed over silicon layer 303 using conventional CMOS processing steps. In one embodiment, gate dielectric 306 is silicon oxide having a thickness in the range of about 40 to 70 Angstroms. It is understood that gate dielectric 306 can include different dielectric materials and thicknesses in other embodiments. Polysilicon gate 307 has a thickness in the range of about 800 to 2000 Angstroms. In accordance with one embodiment of the invention, polysilicon gate 307 has a length (L) of at least about 0.13 microns. In an alternate embodiment, polysilicon gate 307 has a length (L) of at least about 0.20 microns. In yet another embodiment, polysilicon gate 307 has a length (L) of at least about 0.25 microns. The various dimensions and compositions of gate dielectric 306 and polysilicon gate 307 are selected to enable SOI CMOS transistor 300 to have operating voltages and a current carrying capacity that enables this transistor to meet the requirements of an RF switching application.

Lightly doped source and drain regions 304B and 305B are formed by a dopant implant, which is aligned with edges of polysilicon gate 307 and gate dielectric 306. In the described embodiments, SOI transistor 300 is an NMOS transistor, wherein an n-type dopant implant is performed to form lightly doped source and drain regions 304B and 305B. For example, this lightly doped implant may be implemented by implanting arsenic at an energy of about 10 KeV and a dosage of about 5*10¹⁴ ions/cm2

Dielectric sidewall spacers 308 and 309 are then formed using conventional CMOS processing steps. In one embodiment, dielectric sidewall spacers 308-309 are silicon nitride, although other spacer materials are possible.

Source and drain contact regions 304A and 305A are then formed by a dopant implant, which is aligned with edges of dielectric sidewall spacers 308-309. When SOI CMOS transistor 300 is an NMOS transistor, source and drain contact regions 304A and 305A are formed by implanting an n-type dopant. For example, this implant may be implemented by implanting arsenic at an energy of about 40 KeV and a dosage of about 5*10¹⁵ ions/cm2. In general, source/drain contact regions 304A and 305A are more heavily doped (N+) than lightly doped source/drain regions 304B and 305B (N−).

Source contact region 304A and lightly doped source region 304B form the source region 304 of SOI CMOS transistor 300, and drain contact region 305A and lightly doped drain region 305B form the drain region 305 of SOI CMOS transistor 301. A p-type channel region 315 is defined between the source and drain regions 304-305 of SOI CMOS transistor 300. In one embodiment, polysilicon gate 307 has a length (L) such that the length of the channel region 315 is about 0.13 microns or greater. Such a channel length is typically available in a standard SOI CMOS process having a minimum feature size of 0.13 or greater (i.e., a 0.13 micron CMOS process or larger).

An in-situ RF sputter clean is then performed, thereby cleaning the upper surfaces of source contact region 304A, drain contact region 305A and polysilicon gate 307. A layer of nickel (Ni) 310 is then deposited over the resulting structure using, for example, a plasma vapor deposition (PVD) process. In the described embodiments, nickel layer 310 has a thickness of about 80-150 Å. The thickness of nickel layer 310 is selected to provide acceptable resistances and thicknesses to the subsequently formed nickel silicide regions. In one variation, nickel layer 310 may contain a small percentage of platinum (Pt), which will allow the resulting metal silicide to withstand higher thermal budgets. In one embodiment, nickel layer 310 includes up to about 5% platinum. An optional titanium nitride (TiN) capping layer 311 having a thickness of about 100 Å is deposited over nickel layer 310. TiN capping layer 311 helps to avoid agglomeration of nickel layer 310 during subsequent thermal processing.

As illustrated in FIG. 3B, a relatively low temperature (RTP) process 340 is used to cause the deposited nickel layer 310 to react with the underlying silicon regions 304A, 305A and 307, thereby forming nickel-rich silicide regions 321, 322 and 323, respectively. In one embodiment, the RTP process 340 is performed at a temperature of about 280 to 350° C. for a duration of about one minute. In contrast, the fabrication of conventional titanium silicide and cobalt silicide requires temperatures over 600° C. When the RTP process 340 is complete, the composition (phase) of nickel silicide regions 321-323 is primarily Ni₂Si.

As illustrated in FIG. 3C, the capping layer 311 and the unreacted portions of nickel layer 310 are stripped using a wet process 341, which may include the application of a hot sulfuric peroxide mixture (SPM).

As illustrated in FIG. 3D, a second RTP process 342 is used to convert the nickel silicide regions 321-323 having the phase Ni₂Si, into nickel silicide regions 331-333 having the phase NiSi. The NiSi phase of nickel silicide advantageously has a lower resistance than the Ni₂Si phase of nickel silicide. In accordance with one embodiment, the second RTP process 342 is performed at a temperature of about 450° C. for a duration of about one minute.

During the creation of the NiSi nickel silicide regions 331-333 (FIGS. 3A-3D), the nickel present in nickel layer 310 consumes only about 1.8 nm of the underlying silicon regions (e.g., source contact region 304A, drain contact region 305A and polysilicon gate 307) for each nm of deposited nickel. In comparison, each nm of a titanium layer consumes about 2.27 nm of an underlying silicon region to form a titanium silicide (TiSi₂) layer, and each nm of a cobalt layer consumes about 3.65 nm of an underlying silicon region to form a cobalt silicide (CoSi₂) layer. Thus, a relatively thick nickel layer 310 (when compared with a titanium layer or a cobalt layer) can be used to create metal silicide regions having a predetermined thickness. In the above described example, a nickel layer 310 having a thickness of 100 Angstroms results in the consumption of about 180 Angstroms of silicon. However, for the equivalent silicon consumption, an initially deposited titanium layer would be limited to a thickness of about 79 Angstroms (i.e., 180/2.27), and an initially deposited cobalt layer would be limited to a thickness of about 49 Angstroms (i.e., 180/3.65). Under these conditions, the sheet resistance of the nickel silicided regions would be substantially less than the sheet resistances of the corresponding titanium silicide regions or cobalt silicide regions. Stated another way, the present invention allows for the use of a relatively thick deposited nickel layer 310 to provide metal silicide regions having a relatively low sheet resistance for a given metal silicide thickness.

Nickel silicide has previously been used in deep submicron planar CMOS processes having minimum feature sizes of 90 nm and below. The very small feature sizes of the process require the use of a silicide with smaller grain sizes than can be achieved with cobalt or titanium to achieve the resistance targets for these technology nodes. However, nickel silicide has not been employed in older generation SOI CMOS processes (i.e., SOI CMOS processes having minimum feature sizes of 0.13 microns or greater) due to the higher manufacturing cost associated with the fabrication of nickel silicide, and the fact that the post-silicide thermal budgets of these older generation SOI CMOS processes are incompatible with the formation of nickel silicide.

In accordance with one embodiment of the present invention, after the NiSi nickel silicide regions 331-333 are formed (FIGS. 3A-3D), the post-silicidation processing is restricted to temperatures of less than about 550° C. to prevent the nickel silicide regions 331-333 from being converted from the low-resistance NiSi phase to the higher resistance NiSi₂ phase.

As described above, NiSi nickel silicide regions 331-333 cannot handle high thermal budgets. Thus, in accordance with one embodiment, the thermal budget after forming NiSi nickel silicide regions 331-333 is reduced with respect to conventional SOI CMOS processing technologies having minimum feature sizes of 0.13 microns or greater.

As illustrated in FIG. 3E, pre-metal dielectric (PMD) layer 350 is formed over the structure of FIG. 3D. In a conventional 0.13 micron (or larger) SOI CMOS processing technology, pre-metal dielectric layer 350 would be annealed/densified to allow for uniform polishing. However, such annealing would undesirably convert NiSi nickel silicide regions 331-333 to NiSi₂ nickel silicide regions. Thus, in accordance with one embodiment, pre-metal dielectric layer 350 is not annealed. Rather, as illustrated in FIG. 3F, a chemical mechanical polishing (CMP) process 343 is performed on the un-annealed pre-metal dielectric layer 350, thereby creating planarized pre-metal dielectric layer 351, which may have more variation from batch to batch and across the wafer (compared with CMP of an annealed pre-metal dielectric layer). As illustrated in FIG. 3G, a variable (dielectric) capping layer 352 is formed over the planarized pre-metal dielectric layer 351 to control the total thickness of the pre-metal dielectric material. The thickness of pre-metal dielectric layer 351 after the CMP process 343 is fed-forward to select one of several capping layer recipes to achieve a final post-polish and cap dielectric thickness target.

As illustrated in FIG. 3H, contact holes 361-363 are formed through roughly planarized pre-metal dielectric layer 351 and capping layer 352, thereby exposing portions of NiSi nickel silicide regions 331-333 to be contacted. In a conventional 0.13 micron (or greater) SOI CMOS process, a titanium (Ti) liner layer is deposited in the contact holes 361-363, and a rapid thermal process RTP is then performed (at a temperature of about 700° C.) to anneal the liner layer. However, this RTP process would undesirably convert NiSi nickel silicide regions 331-333 to NiSi₂ nickel silicide regions. Thus, in accordance with one embodiment, a modified deposition method is used to form a liner layer 355 in the contact holes 361-363, wherein a RTP process is not used to form this liner layer 355. This modified deposition method is more conformal with respect to the sidewalls of the contact holes 361-363 to provide a more uniform coating. In one embodiment, an ion metal plasma (IMP) titanium liner deposition can be performed to form a titanium liner 355A, followed by an integrated titanium nitride (TiN) deposition to form a titanium nitride layer 355B. Titanium layer 355A and titanium nitride layer 355B form the liner layer 355, which provides the required conformality, adhesion, and electrical properties, without the need for high temperature (greater than about 500° C.) processing.

After the liner layer 355 is deposited, a conventional metal layer (not shown) is deposited over the liner layer 355 to form metal contacts in contact holes 361-363. The remaining back end processing remains unchanged from conventional 0.13 micron (or greater) SOI CMOS processing. That is, the additional metal layers and insulating layers required to form the interconnect structure do not need to be modified to provide an appropriate thermal budget that prevents the NiSi nickel silicide regions 331-333 from being converted to NiSi₂ nickel silicide regions.

Although the methods described above in connection with FIGS. 3A-3H provide a gate silicide region 333 that is fabricated at the same time as (and using the same metal as) the source/drain silicide regions 331-332, it is understood that in other embodiments, the gate silicide region 333 may be separately fabricated using a metal other than nickel (e.g., titanium or cobalt) in alternate embodiments.

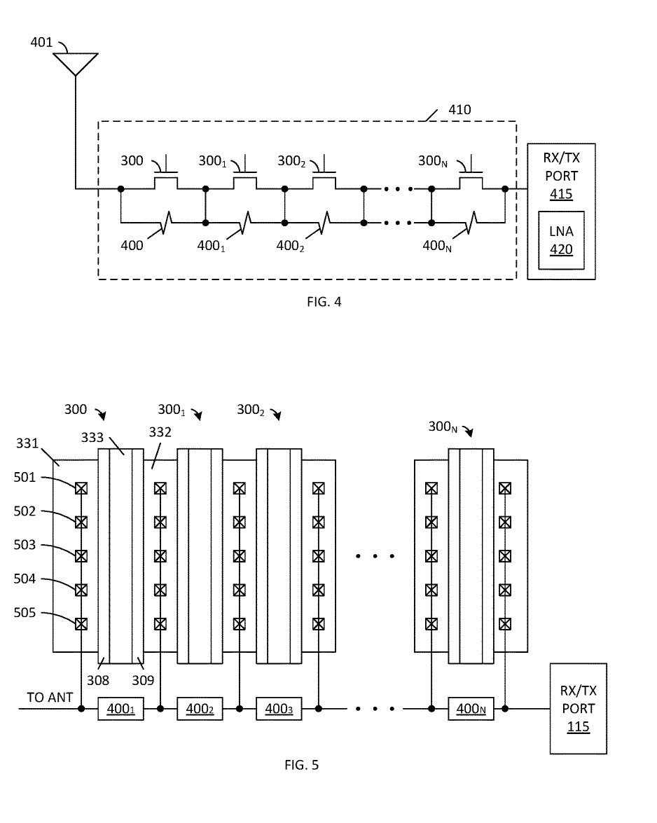

FIG. 4 is a circuit diagram of an RF switch 410 that includes a plurality of series-connected SOI CMOS transistors 300 and 300₁-300_{N} having NiSi nickel silicided source/drain regions, and a plurality of series-connected resistors 400 and 400₁-400_{N}. RF switch 410 is connected between an RF antenna 401 and a communications port 415 (which may be either a receive port or a transmit port). Receive/transmit port 415 includes various circuitry, which may include a low noise amplifier (LNA) 420. In accordance with one embodiment, RF switch 410 and receive/transmit port 415 are fabricated on the same integrated circuit, wherein LNA 420 is constructed using transistors identical to SOI CMOS transistor 300. Advantageously, the NiSi silicided source/drain/gate regions of SOI CMOS transistor 300 enable this transistor to meet the noise requirements associated with the LNA 420.

FIG. 5 is a schematic top view representing the SOI CMOS transistors 300 and 300₁-300_{N} and the resistors 400 and 400₁-400_{N}. In the illustrated embodiment, each of the transistors 300₁-300_{N} is identical to SOI CMOS transistor 300 (see, FIGS. 3A-3H). Various elements of transistor 300, including NiSi nickel silicide regions 331-333 and dielectric sidewall spacers 308-309 are illustrated in FIG. 5. Resistors 400 and 400₁-400_{N} may be implemented using the same polysilicon layer used to form the polysilicon gates of transistors 300 and 300₁-300_{N}. Resistors 400 and 400₁-400_{N} control the voltages across the source/drain regions of transistors 300 and 300₁-300_{N} when these transistors are turned on. In a particular embodiment, resistors 400 and 400₁-400_{N} are designed to have the same resistance (e.g., 10 kOhms), such that the voltage drop across each of the transistors 300 and 300₁-300_{N} is approximately identical. The resistances of resistors 400 and 400₁-400_{N} are sufficiently high that when the transistors 300 and 300₁-300_{N} are off, negligible current flows through these resistors 400 and 400₁-400_{N}.

Within RF switch 410, adjacent transistors share adjacent source/drain regions. For example, the drain region 305 of transistor 300 is continuous with the source region of the adjacent transistor 300₁. Note that multiple contacts (each represented by a box containing an ‘x’) are provided to each of the source/drain regions of transistors 300 and 300₁-300_{N}. For example, multiple contacts 501-505 are provided to the source region 304 of transistor 300 (via nickel silicide region 331). Because the resistances of the nickel silicide regions of transistors 300 and 300₁-300_{N} are relatively low (as described above), the areas of these nickel silicide regions can be relatively small (e.g., on the order of 5 square microns for each nickel silicided source/drain region) and the number of contacts provided to each of these nickel silicide regions can be relatively small (and the spacing between these contacts can be relatively large), while still providing adequate ohmic contact between the contacts and the nickel silicide regions. By reducing the number of contacts, and increasing the spacing of these contacts, the overall off-capacitance (C_{OFF}) of the associated RF switch 410 is advantageously minimized. In accordance with one embodiment, the source/drain contacts are spaced at least about 0.45 microns apart, or two to three times the minimum design rule supported by the process technology.

Table 1 below provides a comparison of active sheet resistances for NiSi nickel silicided N-type regions in accordance with the present invention, and conventional (CoSi₂) cobalt silicided N-type regions for various process conditions. The thicknesses and compositions of the metal layers used to form the silicide regions are listed in Table 1. In Table 1, the term ‘low N+’ refers to a reduced N-type dopant concentration in the source/drain contact regions 304A and 305A, and the term ‘high NLDD’ refers to an increased N-type dopant concentration in the lightly doped regions 304B and 305B. The values in Table 1 represent a range of samples for the given process conditions.

TABLE 1

| Process Condition | Sheet Resistance (Ohms/sq) |
|---|---|
| 100 Å Ni | 11-14 |
| 100 Å Ni (low N+) | 11-12 |
| 70 Å Ni | 16-17.5 |
| 60 Å Co | 18-27.5 |
| 60 Å CO (high NLDD) | 21-27 |
| 60 Å Co (low N+) | 19.5-25.5 |

Note that a 100 Angstrom nickel layer and a 60 Angstrom cobalt layer will result in corresponding metal silicide layers that consume about the same silicon thickness. As illustrated by Table 1, the resulting NiSi nickel silicide regions will exhibit a significantly lower active sheet resistance than the corresponding CoSi₂ cobalt silicide regions. The dopant concentrations of the underling silicon regions do not have a substantial impact on the resulting sheet resistances. Note that reducing the thickness of the nickel layer 310 from 100 Angstroms to 70 Angstroms increases the sheet resistance of the resulting nickel silicide regions 304-305. In accordance with one embodiment, the thickness of the nickel layer 310 is selected to be in the range of about 80 to 150 Angstroms (such that the resulting nickel silicide regions 331-333 have thicknesses in the range of about 190 to 350 Angstroms).

Table 2 below provides a comparison of R_{ON}*C_{OFF} value (figure of merit) for RF switches including SOI CMOS transistors fabricated with NiSi nickel silicide regions and CoSi₂ cobalt silicide regions for various transistor gate lengths. In the examples of Table 2, the RF switch 410 includes eight series-connected SOI CMOS transistors, with a fixed pitch of 0.82 microns between the gate electrodes of these transistors. The R_{ON}*C_{OFF} values in Table 2 are normalized to the R_{ON}*C_{OFF} value of an RF switch fabricated with a 60 Angstrom Cobalt layer and a gate length of 0.26 microns (which is normalized to a value of 1.00).

TABLE 2

| | Normalized | Normalized |
|---|---|---|
| Gate Length | R_{ON} * C_{OFF} | R_{ON} * C_{OFF} |
| (microns) | (100 Å Ni) | (60 Å Co) |
| 0.18 | 0.65 | 0.73 |
| 0.20 | 0.71 | 0.80 |
| 0.22 | 0.78 | 0.86 |
| 0.24 | 0.85 | 0.93 |
| 0.26 | 0.92 | 1.00 |

Note that the RF switches fabricated with NiSi nickel silicide in accordance with the present invention consistently exhibit lower R_{ON}*C_{OFF} values than RF switches fabricated with cobalt silicide. Also note that as the gate length decreases, the R_{ON}*C_{OFF} values decrease. However, as the gate length decreases, the breakdown voltages of the associated transistors also decrease (see, e.g., Table 3 below). As a result, when selecting an optimal gate length of a NiSi nickel silicide SOI CMOS transistor for use in an RF switch, it is not sufficient to simply select the smallest gate length to minimize the R_{ON}*C_{OFF} value. Rather, there is a trade-off between minimizing the R_{ON}*C_{OFF} value and obtaining an adequately high transistor breakdown voltage, as well as adequately high current carrying capability. In accordance with one embodiment, a SOI CMOS transistor having NiSi nickel silicided source/drain regions, and a gate length of at least about 0.2 microns is used to create the RF switch 410.

Table 3 below provides a comparison of the AC breakdown voltages for NiSi nickel silicided SOI CMOS transistors fabricated in accordance with the present invention, and conventional CoSi₂ cobalt silicided SOI CMOS transistors. The AC breakdown voltages in Table 3 are normalized to the AC breakdown voltage of an RF switch fabricated with a 60 Angstrom Cobalt layer and a gate length of 0.18 microns (which is normalized to a value of 1.00).

TABLE 3

| | Normalized | Normalized |
|---|---|---|
| Gate Length | AC breakdown Voltage | AC breakdown Voltage |
| (microns) | (100 Å Ni) | (60 Å Co) |
| 0.18 | 1.00 | 1.00 |
| 0.20 | 1.15 | 1.15 |
| 0.22 | 1.23 | 1.23 |
| 0.24 | 1.35 | 1.31 |
| 0.26 | 1.46 | 1.42 |
| 0.28 | 1.51 | 1.46 |

In general, the SOI CMOS transistors fabricated with NiSi nickel silicide exhibit a breakdown voltage that is greater than or equal to the breakdown voltage of transistors having the same gate lengths and are fabricated with CoSi₂ cobalt silicide.

Although the invention has been described in connection with several embodiments, it is understood that this invention is not limited to the embodiments disclosed, but is capable of various modifications, which would be apparent to a person skilled in the art. For example, the various described p-type regions can be interchanged with the described n-type regions to provide similar results. Thus, the invention is limited only by the following claims.

We claim:

1. A radio frequency (RF) switch comprising:
a plurality of series-connected silicon-on-insulator (SOI) transistors, each having a drain, a source and a gate; and
nickel silicide regions formed on the drain and source of each of the SOI transistors.

2. The RF switch of claim 1, wherein each of the SOI transistors has a gate length of at least about 0.13 microns.

3. The RF switch of claim 1, wherein each of the SOI transistors has a gate length of at least about 0.20 microns.

4. The RF switch of claim 1, wherein each of the SOI transistors has a gate length of at least about 0.25 microns.

5. The RF switch of claim 1, wherein the SOI transistors are fabricated in a silicon layer having a total thickness less than 1000 Angstroms.

6. The RF switch of claim 5, wherein the SOI transistors are fabricated in a silicon layer having a total thickness of about 800 Angstroms.

7. The RF switch of claim 1, wherein the nickel silicide regions have a thickness of about 190 to 350 Angstroms.

8. The RF switch of claim 1, wherein the nickel silicide regions further comprise about 5% platinum.

9. The RF switch of claim 1, further comprising a plurality of contacts electrically connected to each source and drain, wherein the contacts are spaced at least about 0.45 microns apart.

10. The RF switch of claim 1, wherein the SOI transistors are fabricated using an SOI CMOS process having a minimum feature size of at least about 0.13 microns.

11. The RF switch of claim 1, further comprising a plurality of resistors, wherein each of the resistors is coupled across the drain and source of a corresponding one of the SOI transistors.

12. A method of fabricating a radio frequency (RF) switch comprising:
forming a silicon layer over an insulator;
fabricating a plurality of series-connected transistor structures on the silicon layer, wherein the transistors structures include:
a plurality of gates, each having a gate length of at least 0.13 microns; and
a plurality of source/drain regions;
depositing a nickel layer over the plurality of source/drain regions; and
reacting the nickel layer with the plurality of source/drain regions, thereby forming a plurality of nickel silicide regions on the plurality of source/drain regions.

13. The method of claim 12, further comprising:
depositing the nickel layer over the plurality of gates; and
reacting the nickel layer with the plurality of gates, thereby forming a plurality of nickel silicide regions on the plurality of gates.

14. The method of claim 12, further comprising forming the silicon layer to have a thickness of about 1000 Angstroms or less.

15. The method of claim 14, further comprising forming the silicon layer to have a thickness of about 800 Angstroms.

16. The method of claim 12, further comprising introducing up to 5% platinum to the nickel layer.

17. The method of claim 12, further comprising forming a titanium nitride capping layer over the nickel layer prior to reacting the nickel layer.

18. The method of claim 12, further comprising depositing the nickel layer to a thickness in the range of about 80 to 150 Angstroms.

19. The method of claim 12, wherein reacting the nickel layer comprises performing a first anneal to form nickel silicide regions of the nickel phase, Ni₂Si.

20. The method of claim 19, wherein the first anneal is performed at temperatures in the range of about 280° C. and 350° C.

21. The method of claim 19, wherein reacting the nickel layer further comprises stripping unreacted portions of the nickel layer after performing the first anneal.

22. The method of claim 21, wherein reacting the nickel layer further comprises, after stripping unreacted portions of the nickel layer, performing a second anneal to form nickel silicide regions of the nickel phase, NiSi.

23. The method of claim 22, wherein the second anneal is performed at temperatures of about 450° C.

24. The method of claim 12, further comprising:
depositing a pre-metal dielectric layer over the nickel silicide regions;
performing a chemical-mechanical polishing (CMP) operation to planarize the pre-metal dielectric layer, wherein the pre-metal dielectric layer is not annealed prior to the CMP operation.

25. The method of claim 24, further comprising:
forming contact openings through the planarized pre-metal dielectric layer; and
depositing a titanium nitride liner layer in the contact openings; and
depositing a metal contact layer over the titanium nitride layer in the contact openings, wherein the titanium nitride layer is not annealed prior to depositing the metal contact layer.

26. A method of implementing a radio frequency (RF) switch comprising:
routing a radio frequency (RF) signal between an antenna and a communication port using a plurality of series-connected silicon-on-insulator (SOI) CMOS transistors, wherein each of the SOI CMOS transistors includes:
a gate having a length of at least about 0.13 microns; and
a drain and a source, wherein nickel silicide regions are formed on the drain and the source.
